(19) United States
(12) Patent Application Publication
(10) Pub. No.: US 2025/0362453 A1
(43) Pub. Date: Nov. 27, 2025

(54) SEMICONDUCTOR DEVICES WITH DOUBLE SILICON LENS

(71) Applicant: Taiwan Semiconductor Manufacturing Company, Ltd., Hsinchu (TW)

(72) Inventors: Feng-Wei Kuo, Hsinchu City (TW); Wen-Shiang Liao, Tainan City (TW)

(73) Assignee: Taiwan Semiconductor Manufacturing Company, Ltd., Hsinchu (TW)

(21) Appl. No.: 19/287,401

(22) Filed: Jul. 31, 2025

Related U.S. Application Data
(63) Continuation of application No. 18/417,314, filed on Jan. 19, 2024.

(51) Int. Cl. G02B 6/124; G02B 6/12; G02B 6/13; H01L 25/16

(52) U.S. Cl. CPC G02B 6/124; G02B 6/13; H01L 25/167; G02B 2006/12102; G02B 2006/12107

(57) ABSTRACT

A semiconductor device includes a silicon substrate having a first side and a second side opposite to each other, and further having a first region and a second region on. The semiconductor device includes a first silicon lens formed in the first region and along a first surface of the silicon substrate on the first side of the silicon substrate. The semiconductor device includes a second silicon lens formed in the first region and along a second surface of the silicon substrate on the second side of the silicon substrate. The semiconductor device includes a photonic die disposed in the first region and on the second side of the silicon substrate.

### CROSS-REFERENCE TO RELATED APPLICATION

This application is a continuation of U.S. patent application Ser. No. 18/417,314, filed Jan. 19, 2024, which is incorporated herein by reference in their entireties for all purposes.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a multi-chip system including a number of sites, in accordance with some embodiments.

FIG. 2 illustrates an example arrangement of components of a site of the multi-chip system of FIG. 1, in accordance with some embodiments.

FIG. 3 illustrates a cross-sectional view of a portion of the site of FIG. 1, in accordance with some embodiments.

FIG. 4 illustrates a detailed, cross-sectional view of the portion of the site shown in FIG. 3, in accordance with some embodiments.

FIG. 5 illustrates a cross-sectional view of a silicon-based lens embedded in the portion of the site shown in FIG. 3, in accordance with some embodiments.

FIG. 6 illustrates an example flow chart of a method for making the portion of the site shown in FIG. 3, in accordance with some embodiments.

FIG. 7 illustrates an example flow chart of a method for making the silicon-based lens shown in FIG. 5, in accordance with some embodiments.

FIGS. 8-20 illustrate respective cross-sectional views of a portion of a semiconductor package during various fabrication stages, made by the method of FIGS. 6-7, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of a three-dimensional (3D) packages including both an optical device and an electrical device which may be electrically coupled to each other, and the method of forming the same. In certain embodiments, a system on integrated chips (SoIC) can provide advantages including fine pitch (e.g., relatively higher bond density), shorter wire delay of SoIC bonding, or hybrid-laser micro-lens integration and fiber-to-photonic integrated circuit (PIC) assembly in SoIC system, for instance, to reduce photonic packaging resources. The SoIC structure can include or integrate individual systems, such as photonics or optic integrated circuits (ICs), radio-frequency integrated circuits (RFICs), power ICs, analog ICs, mixed-mode ICs, among others. An optic grating coupler (GC) (e.g., for a peak wavelength of about 1310 nanometer (nm)) is provided or used to emit a beam that is mode-matched with a single-mode fiber with a spot diameter of around 9.2 μm, although the spot diameter can include or be configured to other dimensions, greater than or less than 9.2 μm. In some cases, a grating may emit about 63% (e.g., 2 dB) of the input power into each of the upward and downward directions respectively. The beam emitted in the downward direction can expand while traveling through the substrate (e.g., silicon material or other types of substrate materials).

In some configurations, a (e.g., micro) silicon lens can be placed or formed on the front side of the chip (or the front side of the substrate) for collimating the divergent beam from the optic GC. Such silicon-based lenses can serve as an optical input/output (I/O) for the optical device. For example, with configurable dimensions and profiles, the silicon-based lens can collimate a received optical source and generate a focal point for the optical source at a guided-mode resonance component (e.g., a GC) of the optical device. As such, the optical device can have a significantly improved coupling efficiency. Further, with the focal point adjusted right at the grating coupler, a beam size of the optical source can be optimized (e.g., minimized), which can in turn reduce a size of the grating coupler. Accordingly, an area occupied by the optical device may be reduced, which may advantageously spare more area to incorporate more high-performance (e.g., electrical) devices in the package. In some cases, a collimated beam from an external source with the correct diameter may be emitted or launched onto the lens and focused into the spot (e.g., with the spot diameter of around 9.2 μm spot) on the GC.

However, in a single-lens configuration, the GC may not be placed or positioned at the focal point of the lens for beam collimation. In scenarios that the GC is not positioned at the focal point of the lens (or in cases where no lens are provided in or on the substrate), the coupling efficiency may be reduced or a relatively larger beam size may be produced. Further, the curvature radius of the lens may not be easily controlled, e.g., being that the lens is round-shaped, and the process variation may be larger than plane routing. In accordance with various embodiments, the package, as disclosed herein, embeds or otherwise includes a double silicon-based (e.g., silicon, silicon nitride) lens optically coupled to the optical device. The double silicon lenses can be formed on different (opposite) sides of the substrate to improve process variation, including the curvature radius variation from having a single silicon-based lens, e.g., for light refraction to accommodate for or reduce light incident angle error using the double silicon lenses. For example, the package of the technical solution discussed herein can include a first silicon lens formed along a first surface on a first side of a (e.g., silicon) substrate, and a second silicon lens formed along a second surface on a second side of the substrate, thereby forming double lens on different sides of the substrate. By incorporating or forming the double silicon lens, the directionality of the SoIC structure and the coupler efficiency can be enhanced, and fiber light loss can be reduced, while maintaining the beam size.

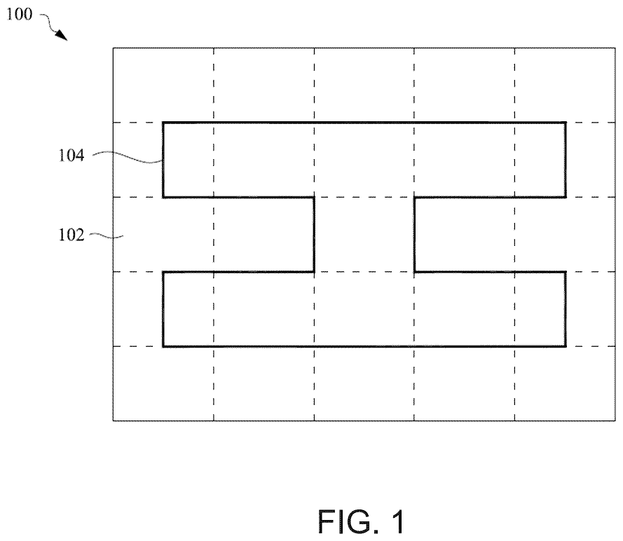

FIG. 1 illustrates a multi-chip system 100, in accordance with various embodiments. The multi-chip system 100 is, e.g., a high performance computing (HPC) system, and includes a plurality of sites 102, each of which may be a separate computing system. Each of the sites 102 may be formed as a (e.g., three-dimensional (3D)) semiconductor package, for example, formed on a common package substrate. Although the system 100 shown in FIG. 1 has twenty sites 102, it should be understood that the system 100 can include any number of sites 102 while remaining within the scope of present disclosure.

The sites 102 are interconnected by an optical pathway 104, which allows the separate computing systems of the sites 102 to communicate with each other. For example, the optical pathway 104 may be a closed loop (or ring) that connects to each site 102 of the multi-chip system 100. As such, each site 102 may communicate with any of the other sites 102 via the optical pathway 104. In an embodiment, the optical pathway 104 includes a plurality of waveguides, and each waveguide connects two of the sites 102 in a peer-to-peer manner. In some embodiments, the optical pathway 104 is a silicon photonic interconnect, although other types of optical pathways could be used.

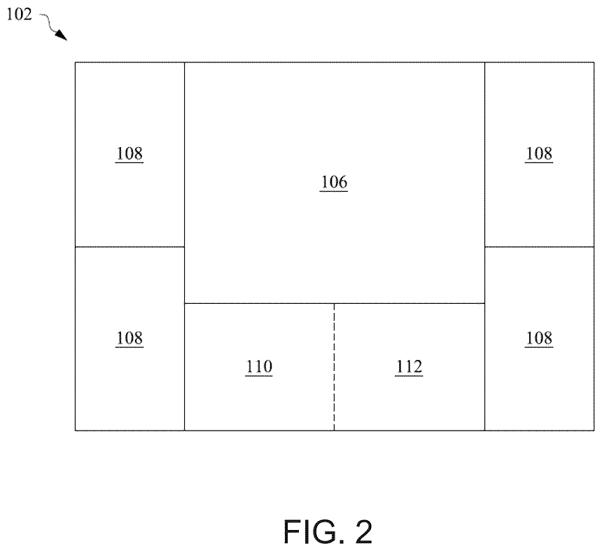

Referring to FIG. 2, an example layout or otherwise arrangement of components (e.g., dies, devices, etc.) in each site 102 is shown, in accordance with various embodiments. As a non-limiting example shown in FIG. 2, each site 102 may include a processor die 106, memory dies 108, an electronic die (an implementation of the electrical device) 110, and a photonic die (an implementation of the optical device) 112. The optical pathway 104 extends under one or more components (or above one or more components depending on the arrangements) of each site 102, but at least extends under the photonic die 112 of each site 102. The sites 102 are interconnected by an electrical pathway (not shown in FIG. 1 or 2, but will be described below).

The processor die 106 may be a central processing unit (CPU), graphics processing unit (GPU), application-specific integrated circuit (ASIC), or the like. The memory dies 108 may be volatile memory such as dynamic random-access memory (DRAM), static random-access memory (SRAM), or the like. In the embodiment shown, each site 102 includes one processor die 106 and four memory dies 108, although it should be appreciated that each site 102 may include more or less memory dies 108 or more processor die 106.

The photonic die 112 can transmit, receive, convert, modulate, demodulate, or otherwise process optical signals. For example, the photonic die 112 can convert electrical signals from the processor die 106 to optical signals, and convert optical signals to electrical signals. The photonic die 112 can communicate such optical signals through the optical pathway 104 (FIG. 1) with one or more other photonic dies. According to various embodiments of the present disclosure, the photonic die 112 can receive the optical signals from a silicon-based lens embedded onto the corresponding site 102, and transmit and/or receive the optical signals via one or more waveguides of the optical pathway 104. As will be discussed in further detail below, the silicon-based lens may be optically coupled to the optical pathway 104 by edge or grating coupling (e.g., via a grating coupler). Such optical signals received through the silicon-based lens may include a test signal configured to test the corresponding photonic die 112, the optical pathway 104, etc., and/or a carrier (e.g., laser) signal. Accordingly, the photonic die 112 is responsible for the input/output (I/O) of optical signals to/from the optical pathway 104. In some embodiments, the optical pathway 104, or at least a portion of it, may be integrated into the photonic die 112.

In various embodiments, the photonic die 112 may be a photonic integrated circuit (PIC), and the electronic die 110 (e.g., sometimes referred to as an electrical die) includes electronic circuits needed to interface the processor die 106 with the photonic die 112. For example, the electronic die 110 may include controllers, transimpedance amplifiers, and the like. The electronic die 110 controls high-frequency signaling of the photonic die 112 according to electrical signals (digital or analog) received from the processor die 106. The electronic die 110 may be an electronic integrated circuit (EIC). Although the processor die 106, memory dies 108, and electronic die 110 are illustrated as being separate dies in the non-limiting example of FIG. 2, it should be appreciated that the sites 102 could each be a system-on-chip (SoC) or a system-on-integrated-circuit (SoIC) device/package. As such, the processing, memory, and/or electronic control functionality may be integrated on the same die or the same substrate.

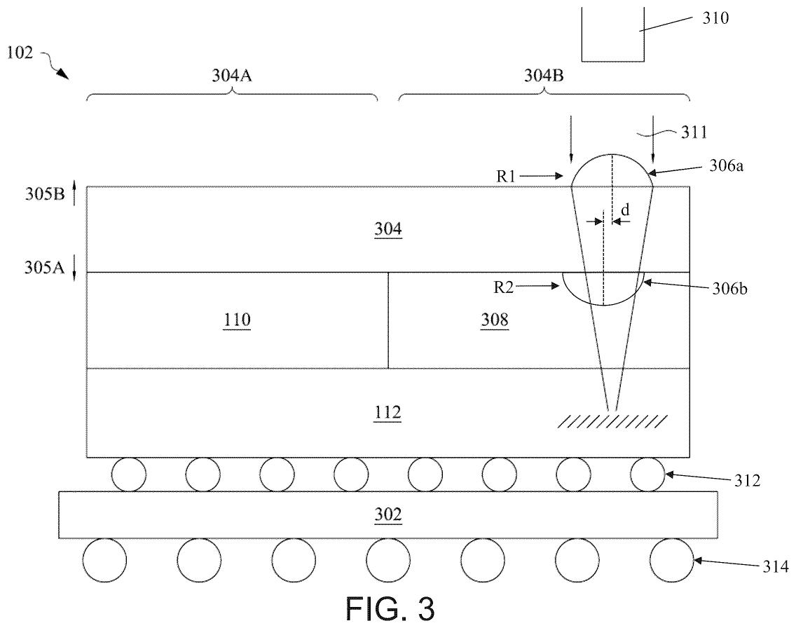

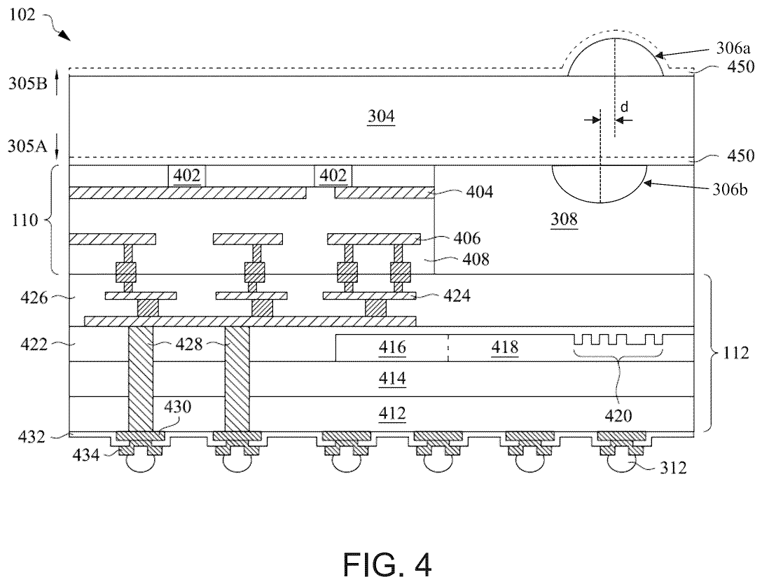

FIG. 3 illustrates a cross-sectional view of a portion of one of the sites 102, in accordance with various embodiments. For example, the portion of the site 102 shown in FIG. 3 includes an electronic die 110 attached to or otherwise stacked over an optical die 112, and such two stacked dies are disposed over a package substrate 302. The cross-sectional view of the site 102, in FIG. 3, is simplified as a schematic diagram, while further details of the site 102 will be shown and discussed in FIG. 4. Further, it should be appreciated that over the package substrate 302, the site 102 can include any of various other dies attached thereto, for example, one or more memory dies 108, one or more processor dies 106, etc., while remaining within the scope of present disclosure.

The electronic die 110 is formed over a substrate 304. The substrate 304 may be a semiconductor substrate, such as a bulk semiconductor or the like, which may be doped (e.g., with a p-type or an n-type dopant) or undoped. The substrate 304 may be a wafer, such as a silicon wafer. Other substrates, such as a multi-layered or gradient substrate may also be used. In some embodiments, the semiconductor material of the substrate 304 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In an embodiment, the substrate 304 is a silicon wafer, e.g., a 12 inch silicon wafer. In some embodiments, the substrate 304 can be formed with a thickness, not limited to, between about 300 micrometer (μm) to about 1000 μm or larger than 1000 μm, depending on the configuration.

In some embodiments, the substrate 304 may be referred to as having a front side or surface 305A (e.g., sometimes referred to as a second side (or a first side depending on the arrangement)), and a back side or surface 305B (e.g., sometimes referred to as a first side (or a second side depending on the arrangement)), as shown. Generally, the electronic die 110 includes a number of device features or structures (e.g., transistors) formed along the front surface 305A, and a number of conductive features (sometimes referred to as front side interconnect structures) formed over these device structures on the front side 305A. However, it should be understood that the electronic die 110 can include a number of other conductive features (sometimes referred to as back side interconnect structures) formed on the back side 305B, while remaining within the scope of present disclosure.

Further, the substrate 304 has several lateral regions or areas, including but not limited to, a first region 304B and a second region 304A. In some arrangements, the first region and the second region may be interchanged. In some embodiments, the electronic die 110 can be formed in the second region 304A, while in the first region 304B and on the back side 305B of the substrate 304, a silicon-based lens 306a (e.g., sometimes referred to as a first silicon lens) is formed. Specifically, the silicon-based lens 306a can be (e.g., vertically) aligned with a light source/provider 310 providing photonic energy (e.g., light) 311 for the photonic die 112, with a dielectric layer 308 (e.g., silicon oxide, silicon nitride, a combination thereof, or the like) interposed therebetween. For example, the light source/provider 310 may include an optical fiber that transmits photonic energy. The dielectric layer 308 can be formed with a thickness of, but not limited to, between about 0 μm to about 50 μm, or greater than 8 μm, depending on the configuration. Further to the formation of the silicon-based lens 306a, a second silicon-based lens 306b is formed on the front side 305A of the substrate 304. In some implementations, one or both of the silicon-based lenses 306a, 306b can sometimes be referred to as silicon-based lens(es) 306. The silicon-based lens 306a can be (e.g., vertically) aligned with the silicon-based lens 306b. In some cases, the silicon-based lens 306a can be (e.g., vertically) offset (or laterally shifted) from the silicon-based lens 306b by a predetermined (or configurable) distance, such as, but not limited to a range of around 0 μm to around 100 μm, for example.

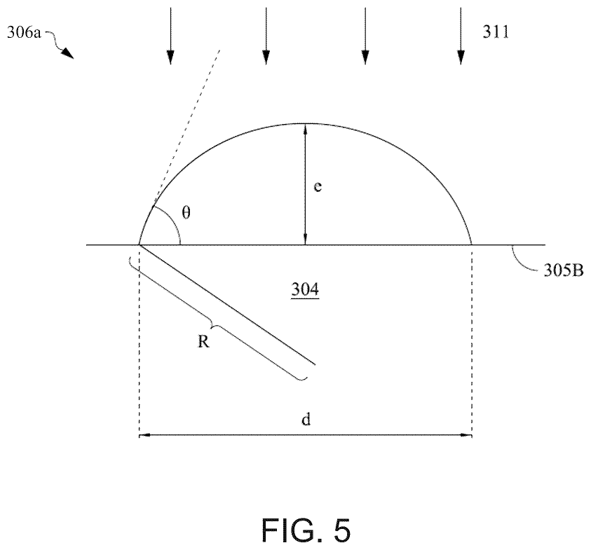

As a result, an optical transmission path extending from the light source/provider 310 to the silicon-based lenses 306 exists. As will be shown below in FIG. 4, such an optical transmission path is free from any conductive (e.g., metal) feature, thereby substantially limiting interference from conductive features. The dimensions and profile of the silicon-based lens 306 (e.g., silicon-based lens 306a and/or silicon-based lens 306b), e.g., a radius of curvature, a thickness, a diameter, an angle, etc., can be configured according to characteristics (e.g., a range of wavelengths) of the light source 311. The silicon-based lens 306b can be composed of similar materials as the silicon-based lens 306a. The silicon-based lens 306b may be formed in a similar manner or using a similar technique (e.g., at least one suitable etching technique) as the silicon-based lens 306a, such as described in conjunction with but not limited to at least one of FIGS. 5-20. As such, when an overlying light source 311 is received by the silicon-based lens 306a, the silicon-based lens 306a can collimate the light source 311, through the substrate 304, the silicon-based lens 306b, and dielectric layer 308, at a focal point that is about a position of the light source/provider 310. Using both the silicon-based lens 306a and the silicon-based lens 306b can improve curvature radius variation, for instance, over having a single silicon-based lens.

In various configurations, the silicon-based lenses 306 can be composed of at least one suitable material, such as silicon or silicon nitride, etc. The silicon-based lenses 306 may be composed of a similar or different material from the substrate 304. In some cases, the silicon-based lenses 306 can be formed by using at least one suitable etching technique on the substrate 304. For example, the silicon-based lens 306a can be formed by (e.g., directly) etching various portions of the back side 305B of the substrate 304. The silicon-based lens 306b can be formed by etching various portions of the front side 305A of the substrate 304. The process for forming the silicon-based lenses 306 can be described in conjunction with but not limited to FIGS. 5-20. In some other cases, the silicon-based lenses 306 can be formed by using at least one deposition technique. For example, the silicon-based lens 306a can be formed by depositing the material (e.g., silicon) on the surface of the back side 305B of the substrate 304. The silicon-based lens 306b can be formed by depositing the material (e.g., silicon) on the surface of the front side 305A of the substrate 304.

The dimension of at least one of the silicon-based lenses 306 can be configured or structured to compensate for the potential offset (or shift) of the fiber (e.g., the optical fiber or an optical source). For example, the diameter of at least one of the silicon-based lenses 306 can be between, although not limited to, about 10 μm to about 500 μm. The maximum diameter of at least one of the silicon-based lenses 306 can be configured to above 100 μm, for example. The thickness (e.g., height) of at least one of the silicon-based lenses 306 can be, but not limited to, between about 1 μm to about 50 μm, where the maximum thickness of the silicon-based lenses 306 may be above 5 μm, for example. At least one of a first curvature radius (R1) of the silicon-based lens 306a or a second curvature radius (R2) of the silicon-based lens 306b can be, but not limited to, between about 100 μm to about 500 μm. At least one of the first curvature radius of the silicon-based lens 306a or the second curvature radius of the silicon-based lens 306b can be greater than, but not limited to, 290 μm. One or more configurations (e.g., diameter, thickness, or curvature radius) of the silicon-based lens 306a can be similar to or different from the silicon-based lens 306b. For example, the diameter of the silicon-based lens 306a may be similar to or different from the diameter of the silicon-based lens 306b. The thickness (or height) of the silicon-based lens 306a may be similar to or different from the thickness of the silicon-based lens 306b. The curvature radius of the silicon-based lens 306a may be similar to or different from the curvature radius of the silicon-based lens 306b.

In some cases, the silicon-based lens 306a can be (e.g., vertically) aligned with the silicon-based lens 306b. In some other cases, the silicon-based lens 306a can be (e.g., vertically) offset from the silicon-based lens 306b by a distance (d). For example, the (e.g., vertical) offset distance between the silicon-based lens 306a and the silicon-based lens 306b can be between about 0 μm to about 100 μm or between about 0 μm to about −100 μm. The optical fiber angle can be configured to, but not limited to, between 5° to 15°, according to the position of at least one of the silicon-based lenses 306. The optical fiber angle may be described or shown in conjunction with but not limited to FIG. 3, such as the angle at which an optical fiber (e.g., associated with the light source/provider 310) is oriented or positioned with respect to the silicon-based lens 306a, the surface of the substrate 304, or other components of the site 102, for example. The features of at least one of the silicon-based lenses 306 can be described in conjunction with, but not limited to, at least FIG. 5.

The site 102 further includes a number of (first) conductive connectors 312, and number of (second) conductive connectors 314. The first conductive connectors 312 can electrically and/or physically couple various dies (e.g., the stacked electronic die 110 and optical die 112) to the package substrate 302, and the second conductive connectors 314 can electrically and/or physically couple the package substrate 302 to one or more other devices/packages. For example, the package substrate 302 can be coupled to at least the photonic die 112 via one or more of the first conductive connectors 312. The package substrate 302 can be coupled to the one or more other devices/packages via one or more of the second conductive connectors 314.

Referring next to FIG. 4, the electronic die 110, disposed in the second region 304A and on the second side 305A of the substrate 304, includes a number of device features 402 formed along the front side surface of the substrate 304. The device features may be partially or fully overlaid by a dielectric layer 404. Over the dielectric layer 404 (when flipping the site 102 of FIG. 2), a number of conductive features 406 are formed in a dielectric layer 408. The dielectric layers 404 and 408 may be formed of the same material or respectively different materials selected from the group consisting of: silicon oxide, silicon nitride, a low-k dielectric material, and combinations thereof. The conductive features 406 may include lines and vias, and may be formed by a damascene process, e.g., dual damascene, single damascene, or the like. The conductive features 406 may be disposed in a number of layers or levels, sometimes referred to as metallization layers. Generally, the metallization layers disposed closest to and farthest from the device features 402 may be referred to as M0 (the bottommost metallization layer) and Mx (the topmost metallization layer), respectively. Over the Mx, a number of pads (not shown) may be formed to electrically connect the conductive features 406 therein to conductive features of the photonic die 112.

The photonic die 112 may be formed on a semiconductor-on-insulator (SOI) substrate, which includes a layer of semiconductor material formed on an insulator layer. The insulator layer may be, for example, a buried oxide (BOX) layer, a silicon oxide layer, or the like. The insulator layer is provided on a semiconductor material, typically a silicon or glass substrate. As shown in FIG. 4, layers 412 and 414 may represent such underlying semiconductor material and BOX layer, respectively.

In addition, the photonic die 112 can include a number of device features 416 (e.g., photodiodes) and a number of waveguides 418 formed in the overlaying semiconductor material (not shown). The front side (or surface) of such an overlaying semiconductor material is patterned to form the waveguide 418. Patterning the overlaying semiconductor material may be accomplished with acceptable photolithography and etching techniques. In particular, openings are etched in the overlaying semiconductor material, and remaining portions of the overlaying semiconductor material can form the waveguide 418. The BOX layer 414 may act as an etch stop layer for the etching process.

The waveguide 418 can be disposed on the front surface 305A (e.g., the second side) of the substrate 304. The waveguide 418 can include one or more grating couplers 420, which are formed in top portions of the waveguide 418. The grating coupler 420 can allow the waveguide 418 to transmit light to or receive light from the overlying light source or optical signal source (e.g., through both the silicon-based lens 306a and silicon-based lens 306b). The grating coupler 420 may be formed by acceptable photolithography and etching techniques. In an embodiment, the grating coupler 420 is formed after the waveguide 418 is defined. The grating coupler 420 can be composed of silicon-based materials. The dimension of the grating coupler 420 can include a thickness of, but not limited to, greater than 200 nm with a range of around 100 nm to 1000 nm, for example. For example, a photoresist may be formed and developed on the front side of the overlaying semiconductor material (e.g., on the waveguide 418 and in the recesses defining them). The photoresist may be patterned with openings corresponding to the grating coupler 420. One or more etching processes may be performed using the patterned photoresist as an etching mask. In particular, the front side of the overlaying semiconductor material may be etched to form recesses in the waveguide 418, thereby defining the grating coupler 420. The etching processes may be an anisotropic wet or dry etch.

The photonic die 112 further includes a dielectric layer 422 formed over the device features 416 and waveguide 418. The dielectric layer 422 may also be formed in the recesses defining the waveguide 418 and the grating coupler 420. The dielectric layer 422 may be formed of silicon oxide, silicon nitride, a combination thereof, or the like, and may be formed by chemical vapor deposition (CVD), physical vapor deposition (PVD), atomic layer deposition (ALD), a spin-on-dielectric process, the like, or a combination thereof. After formation, the dielectric layer 422 may be planarized, such as by a chemical mechanical polish (CMP) or a mechanical grinding, to avoid transfer of the pattern of the waveguide 418 to the dielectric layer 422. In an embodiment, the dielectric layer 422 is an oxide, such as silicon oxide. Due to the difference in refractive indices of the materials of the waveguide 418 and the dielectric layer 422, the waveguide 418 has high internal reflections such that light is confined in the waveguide 418, depending on the wavelength of the light and the reflective indices of the respective materials. In an embodiment, the refractive index of the material of the waveguide 418 is higher than the refractive index of the material of the dielectric layer 422.

Over the dielectric layer 422 (as shown in FIG. 2), a number of conductive features 424 are formed in a dielectric layer 426. The dielectric layers 422 and 426 may be formed of the same material or respectively different materials selected from the group consisting of: silicon oxide, silicon nitride, a low-k dielectric material, and combinations thereof. The refractive index of the material of the waveguide 418 is higher than a refractive index of the material of the dielectric layer 426. The conductive features 424 may include lines and vias, and may be formed by a damascene process, e.g., dual damascene, single damascene, or the like. The conductive features 424 may be disposed in a number of layers or levels, sometimes referred to as metallization layers. Generally, the metallization layers disposed closest to and farthest from the device features 416 may be referred to as M0 (the bottommost metallization layer) and Mx (the topmost metallization layer), respectively. Over the Mx, a number of pads (not shown) may be formed to electrically connect the conductive features 424 therein to conductive features 406 of the electronic die 110, i.e., the electronic die 110 being bonded or otherwise attached to the photonic die 112.

In some embodiments, bonding between the electronic die 110 and photonic die 112 may not include any bump structure, i.e., bumpless. However, in some other embodiments, the bonding between the electronic die 110 and photonic die 112 may be established through a number of bump structures. For example, the bonding may be hybrid bonding, fusion bonding, direct bonding, dielectric bonding, metal bonding, solder joints (e.g., microbumps), or the like.

As a non-limiting example, the electronic die 110 is bonded to the photonic die 112 by hybrid bonding. In such embodiments, covalent bonds are formed with oxide layers, such as the dielectric layer 408 of the electronic die 110 and the dielectric layer 426 of the photonic die 112. Before performing the bonding, a surface treatment may be performed on the electronic die 110. Next, a pre-bonding process may be performed, where respective pads or conductive features of the electronic die 110 and the photonic die 112 are aligned. The electronic die 110 and the photonic die 112 are pressed against together to form weak bonds. After the pre-bonding process, the electronic die 110 and the photonic die 112 are annealed to strengthen the weak bonds. During the annealing, OH bonds in the top of the dielectric layers break to form Si—O—Si bonds between the electronic die 110 and the photonic die 112, thereby strengthening the bonds.

As shown in FIG. 4, an optical transmission path extending from the grating coupler 420 of the photonic die 112 to the silicon-based lenses 306, including to the silicon-based lens 306b (e.g., the second silicon lens) and the silicon-based lens 306a (e.g., the first silicon lens), exists. In such cases, the silicon-based lens 306b can be positioned between the silicon-based lens 306a and the grating coupler 420. In other arrangements, the silicon-based lens 306a may be positioned between the silicon-based lens 306b and the grating coupler 420. In various embodiments, such an optical transmission path is free from any of the conductive features 406 or conductive features 424. Stated another way, along this optical transmission path, no components formed of a conductive material exist, which can substantially limit interference induced by conductive features.

The photonic die 112 further includes a number of vias 428 extending through the dielectric layer 422, the BOX layer 414, and the underlying semiconductor material 412. The vias 428 may be formed by filling a number of openings that extend through the dielectric layer 422, the BOX layer 414, and the underlying semiconductor material 412 with a conductive material. The conductive material is formed in the openings using, for example, electrochemical plating (ECP) or electro-less plating. The conductive material may be a metallic material including a metal or a metal alloy such as copper, silver, gold, tungsten, cobalt, aluminum, or alloys thereof. A planarization process, such as a CMP or mechanical grinding may be performed to remove excess conductive material along a (e.g., back side) surface of the underlying semiconductor material 412. In various embodiments, the vias 428 can electrically couple the conductive features 424 of the photonic die 112, which are electrically coupled to the conductive features 406 of the electronic die 110, to the conductive connectors 312.

Over the back side surface of the underlying semiconductor material 412, the site 102 further includes conductive pads 430, some of which can be electrically in contact with the vias 428. The conductive pads 430 may be aluminum pads or aluminum-copper pads, although other metallic pads may be used.

A passivation film 432 may be formed over the back side surface of the underlying semiconductor material 412, covering the conductive pads 430. The passivation film 432 may be formed from a dielectric material, such as silicon oxide, silicon nitride, the like, or combinations thereof. Openings are formed through the passivation film 432 to expose (e.g., central) portions of the conductive pads 430.

Underbump metallization (UBM) 434 may be formed on the conductive pads 430 and passivation film 432. The UBM 434 may be formed by forming a blanket conductive layer on the passivation film 432 and in the openings, such as by electroplating. The conductive layer may be formed from copper, a copper alloy, silver, gold, aluminum, nickel, the like, and combinations thereof. The conductive layer may be patterned to form the UBM 434.

The conductive connectors 312 are formed on the UBM 434, such as disposed on a first side of the photonic die 112 opposite to a second side of the photonic die 112 which faces the substrate 304. The conductive connectors 312 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 312 may include a conductive material such as solder, copper, aluminum, gold, nickel, silver, palladium, tin, the like, or a combination thereof. In some embodiments, the conductive connectors 312 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 312 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed over the conductive connectors 312. The metal cap layer may include nickel, tin, tin-lead, gold, silver, palladium, indium, nickel-palladium-gold, nickel-gold, the like, or a combination thereof and may be formed by a plating process.

In some embodiments, the site 102 further includes one or more anti-reflection coating (ACR) layers 450 formed on at least one of the front surface 305A or the back surface 305B of the substrate 304. The ARC layer 450 may be formed over the silicon-based lens 306a. In some cases, the ARC layer 450 may be formed under (or over depending on the configuration) the silicon-based lens 306b. The ARC layer 450 may be implemented as a multi-layer of anti-reflective materials such as, for example, silicon, silicon nitride, silicon oxide, titanium, titanium nitride, aluminum, aluminum oxide, silicon oxynitride, combinations of these, or the like. For example, the ARC layer 450 can include a first silicon oxide (e.g., with a thickness of about 1000 angstroms (Å)), a first silicon nitride (e.g., with a thickness of about 500 Å), a second silicon oxide (e.g., with a thickness of about 2400 Å), and a second silicon nitride (e.g., with a thickness of about 2200 Å) stacked on top of one another. In such an embodiment, the ARC layer 450 (or each of its anti-reflective materials) may be formed using a deposition process such as CVD, PVD, or the like. However, any suitable material and method of formation may be used.

FIG. 5 illustrates an enlarged view of the silicon-based lens 306 (e.g., at least of the silicon-based lens 306a or the silicon-based lens 306b), in accordance with various embodiments. Although FIG. 5 provides the silicon-based lens 306a for exemplary purposes, one or more features of the silicon-based lens 306a can be described similarly for the silicon-based lens 306b, such as the dimension, curvature radius, thickness, etc., of the silicon-based lenses 306. As shown in the example of FIG. 5, the silicon-based lens 306a (or the silicon-based lens 306b) has a hemisphere profile, or sometimes referred to as a plano-convex profile, with one spherical surface protruding away from the back side surface 305B and one flat surface substantially aligned with the back side surface 305B. However, it should be understood that the silicon-based lens 306a or the silicon-based lens 306b can have any of various other profiles such as, for example, a double-convex profile, a positive meniscus profile, a positive achromatic profile, etc., as long as the silicon-based lens 306a and the silicon-based lens 306b can generate a focal point at the grating coupler 420 (FIG. 4), while remaining within the scope of present disclosure. With the formation of the silicon-based lens 306a and the silicon-based lens 306b, the two silicon lenses can collectively provide a focal point at the grating coupler 420.

Further, various dimensions of the silicon-based lens 306a (or the silicon-based lens 306b) may be configured to collimate the optical source 311 and cause it to be focused at the grating coupler 420. For example, the silicon-based lens 306a has a thickness “e” which is defined as a maximum height from the flat surface to the spherical surface, an angle “θ” which is defined as the angle between an tangential line at an end of the spherical surface and an end of the flat surface, a radius of curvature “R” of the spherical surface, and a diameter “d” of the silicon-based lens 306a. As a non-limiting example, the thickness (e) may be in the range of about 1 μm to about 50 μm, the angle (θ) (e.g., optical fiber angle) may be in the range of about 5° to about 15°, the radius (R) may be in the range of about 100 μm to about 500 μm, and the diameter (d) may be in the range of about 10 μm to about 500 μm. In some embodiments, the diameter (d) may be formed as at least 100 μm to compensate for an offset of the optical source (e.g., an optical fiber). In some embodiments, the angle (θ) may be formed in the above-identified range so as to optimize a coupling efficiency of the silicon-based lens 306a. In some embodiments, the radius (R) may be formed as around or greater than 290 μm also for optimizing the coupling efficiency of the silicon-based lens 306a. In some embodiments, the radius (R) may be in the range of about 100 μm to about 500 μm.

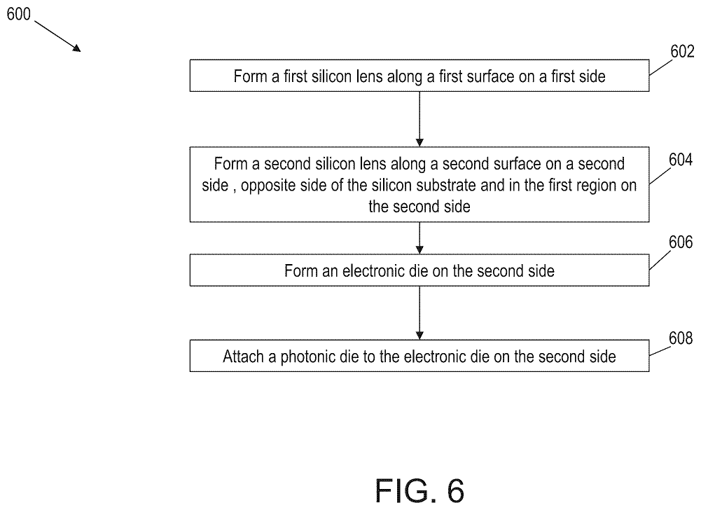

FIG. 6 illustrates a flow chart of an example method 600 for forming at least a portion of a semiconductor package, in accordance with some embodiments. It should be noted that the method 600 is merely an example, and is not intended to limit the present disclosure. Accordingly, it is understood that the order of operation of the method 600 of FIG. 6 can change, that additional operations may be provided before, during, and after the method 600 of FIG. 6, and that some other operations may only be described briefly herein.

Such a semiconductor package, made by the method 600, may include at least an electronic die and a photonic die operatively and physically coupled to each other, and further include a silicon-based lens operatively (e.g., optically) coupled to the photonic die. For example, the semiconductor package may include a portion of the site 102, as discussed above. Accordingly, operations of the method 600 will be discussed in conjunction with the components discussed with respect to FIGS. 3-5.

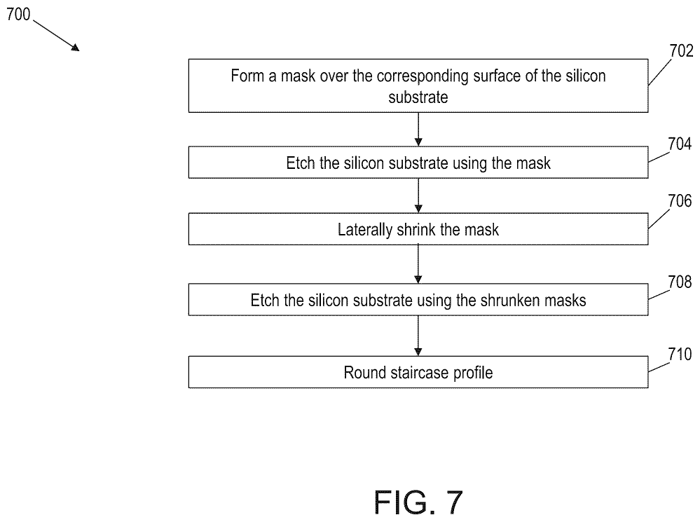

The method 600 starts with operation 602 of forming a first silicon lens (e.g., 306a) along a first surface on a first side (e.g., 305B, sometimes referred to as a first side surface) of the substrate (e.g., 304). For example, the silicon-based lens 306a is formed on a back side surface (e.g., 305B) of the substrate 304. Further, the silicon-based lens 306a is formed in a first region (e.g., 304B) of the substrate 304. In some embodiments, the silicon-based lens 306a is formed with a plano-convex profile through a number of photolithography and etching processes, which will be discussed in further detail in FIG. 7.

The method 600 proceeds to operation 604 of forming a second silicon lens (e.g., 306b) along a second surface on a second side (e.g., 305A, sometimes referred to as a second side surface) of the substrate (e.g., 304). For example, the silicon-based lens 306b is formed on a front side surface (e.g., 305A) of the substrate 304. The front side surface is the opposite side of the substrate 304 to the back side surface. Further, the silicon-based lens 306b is formed in the first region (e.g., 304B) of the substrate 304. In some embodiments, the silicon-based lens 306b is formed with a plano-convex profile through a number of photolithography and etching processes, which will be discussed in further detail in FIG. 7, such as similar to the silicon-based lens 306a.

The method 600 proceeds to operation 606 of forming an electronic die over the second surface (side) (e.g., 305A) of the substrate (e.g., 304). The electronic die can be formed in a second region (e.g., 304A) of the substrate, where the second region is laterally next to the first region of the substrate. For example, an electronic die (e.g., 110), including a number of electrical device features (e.g., 402) and conductive features (e.g., 406), may be formed over the front side surface (e.g., 305A) of the substrate (e.g., 304). Further, the electronic die 110 may be formed in a second region (e.g., 304A) of the substrate 304 where the silicon-based lenses 306 are not configured to be formed. In some embodiments, the first region of the substrate may be referred to as a part of the electronic die 110.

The method 600 proceeds to operation 608 of attaching a photonic die to the electronic die on the second side of the substrate (e.g., 305A). For example, prior to, concurrently with, or subsequently to forming the electronic die 110 (and the silicon-based lenses 306) on the substrate 304, a photonic die (e.g., 112) is formed over the front side surface (e.g., 305A) of the substrate (e.g., an SOI including the underlying semiconductor material 412, BOX 414, and an overlaying semiconductor material). In some embodiments, the photonic die 112 includes a number of optical device features (e.g., 416), a number of waveguides (e.g., 418) with at least a grating coupler (e.g., 420), and a number of conductive features (e.g., 424). The grating coupler (e.g., 420) can be vertically aligned with at least one of the silicon-based lenses (e.g., 306a or 306b), such as described in conjunction with but not limited to at least one of FIGS. 3-4.

Continuing with the same example, upon forming the photonic die 112 and the electronic die 110, the two dies may attach to each other through various bonding techniques such as, for example, hybrid bonding, fusion bonding, direct bonding, dielectric bonding, metal bonding, solder joints (e.g., microbumps), or the like. In some embodiments, the electronic die 110 may be bonded to the photonic die 112, with the conductive features 406 (of the electronic die 110) facing the conductive features 424 (of the photonic die 112). Stated another way, the electronic die 110 can be bonded to the photonic die 112, with their respective front side surfaces facing each other, thereby causing the silicon-based lens 306a to be disposed on a back side (opposite) surface (e.g., 305B) of the substrate 304 where the electronic die 110 is formed, and the silicon-based lens 306b to be disposed on a front side (same) surface (e.g., 305A) of the substrate 304 where the electronic die 110 is formed.

In some embodiments, the electronic die and photonic die can be attached to a package substrate. For example, upon bonding the photonic die 112 and the electronic die 110 to each other, such bonded dies may be attached to a package substrate (e.g., 302). In some embodiments, the bonded photonic die 112 and electronic die 110 may be attached to the package substrate 302 via a number of bump structures (e.g., 312). Further, the bump structures 312 may be formed on a front side (opposite) surface of the substrate where the photonic die 112 is formed.

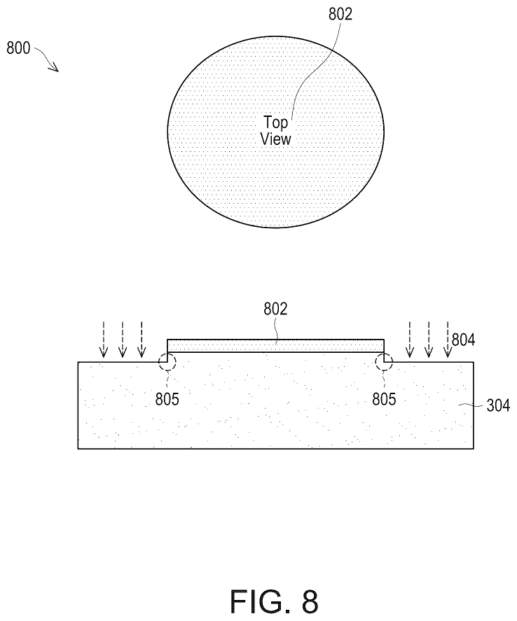

As mentioned above, operation 602 (or operation 604) includes a number of process steps/operations to form the silicon-based lens (e.g., 306a or 306b). FIG. 7 illustrates a flow chart including such operations. In some embodiments, operations of the method 700 may be associated with cross-sectional views of a portion of an example semiconductor package 800, including an embedded silicon-based lens, at various fabrication stages as shown in FIGS. 8-20, respectively.

In brief overview, the method 700 starts with operation 702 forming a first mask over the first (back) surface/side of the silicon substrate. The method 700 next proceeds to operation 704 of etching the substrate (from the back side) using the first mask. The method 700 proceeds to operation 706 of laterally shrinking the mask (e.g., the first mask) to form a second mask. The method 700 proceeds to operation 708 of etching the silicon substrate (from the back side) using the shrunken masks. In various embodiments, at least one of the operations 706 and 708 may be repeated a certain number of times until a desired staircase profile is formed on the back side of the first substrate. Following formation of the staircase profile, the method 700 proceeds to operation 710 of rounding the staircase profile to form the silicon-based lens.

Corresponding to operation 702 of FIG. 7, FIG. 8 is a cross-sectional view and a top view of the semiconductor package 800 in which the back side of a substrate 304 (e.g., back side 305B) is overlaid by a (e.g., hard) mask 802 (e.g., first mask at this stage/operation), in accordance with various embodiments. It should be noted that the substrate 304 of FIG. 8 (and the following figures) are shown with its upside down, and thus, the mask 802 is formed on top of the substrate 304, such as along the first surface or the first side of the silicon substrate. Further, such as based on the method 600, one or more electronic dies may be formed prior to or subsequently to performing the method 700 (to form a silicon-based lens).

The mask 802 may include or be composed of silicon nitride, photoresist, or other materials. The mask 802 may be formed in an elliptic shape, circular shape, among other suitable shapes for etching the silicon substrate 304. In some embodiments, the mask 802 may be formed as a single structure (e.g., one portion). In some other embodiments, the mask 802 may include a number of portions (not shown) overlaying different portions along a corresponding surface of the substrate 304. The mask 802 can be formed or positioned on the corresponding surface (side) at or around the first region (e.g., 304B) of the silicon substrate. The silicon-based lens 306a may be referred to as a first silicon lens, and the silicon-based lens 306b may be referred to as a second silicon lens. The corresponding surface of the substrate 304 is based on whether the operations or processes are used to form the first silicon lens or the second silicon lens. For example, the mask 802 can be formed on the first side 305B of the silicon substrate to form the first silicon lens and formed on the second side 305A of the silicon substrate to form the second silicon lens.

Subsequent to forming the mask 802, and corresponding to operation 704 of FIG. 7, FIG. 8 shows a first etching process 804 performed on the surface (e.g., the back surface side or the front surface side) of the substrate 304 using the mask 802, in accordance with various embodiments. The first etching process 804 may be a wet etching process (based on etchants such as, NH₄OH, HNO₃, or combinations thereof) or a dry etching process (based on etchants such as, NF₃, F₂, Cl₂, or combinations thereof). An amount of the substrate 304 etched by the etching process 804 may be controlled through a length of time (or duration) of the etching process 804. Based on the patterns of the mask 802, the surface may present a donut shape (when viewed from the top), in which the donut shape is presented as a recessed portion with respect to a remaining portion that is overlaid by the mask 802, for example. Specifically, the remaining portion and the recessed portion may form a step, e.g., 805 as indicated in FIG. 8.

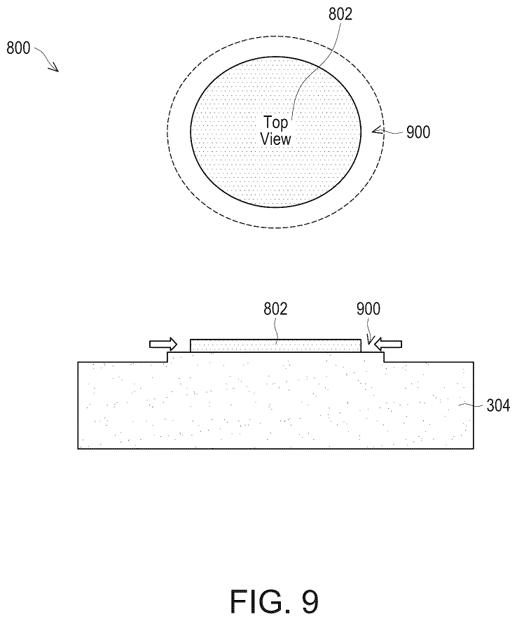

Corresponding to operation 706 of FIG. 7, FIG. 9 is a cross-sectional view and a top view of the semiconductor package 800 in which the mask 802 (e.g., the first mask) is shrunken, e.g., forming a second mask with a diameter less than the first mask, in accordance with various embodiments. At least one suitable etching technique, such as but not limited to plasma ashing, can be utilized to shrink (e.g., remove a portion of) the mask 802, without shrinking other structures of the semiconductor package 800. The etching technique can be used to uniformly recess or shrink the mask 802. As shown, the mask 802 of FIG. 9 includes a relatively smaller diameter compared to the mask 802 of FIG. 8 (e.g., before laterally shrinking the mask 802). For example, the mask 802 is laterally shrunken (e.g., in diameter) to expose further exposed portions (e.g., portion 900) of the surface of the substrate 304. The exposed portions of the surface from laterally shrinking the mask 802 may form a donut shape, for example.

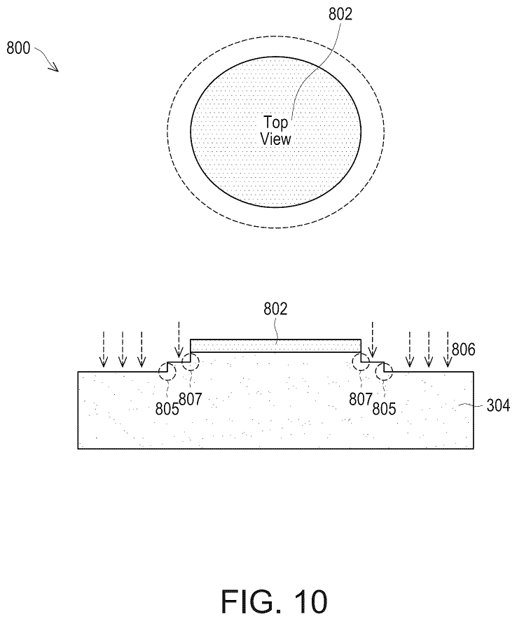

Corresponding to operation 708 of FIG. 7, FIG. 10 is a cross-sectional view and a top view of the semiconductor package 800 in which a second etching process 806 is performed on the surface of the substrate 304 using the (e.g., shrunken) mask 802, in accordance with various embodiments. The second etching process 806 may be a wet etching process (based on etchants such as, NH₄OH, HNO₃, or combinations thereof) or a dry etching process (based on etchants such as, NF₃, F₂, Cl₂, or combinations thereof). The second etching process 806 may be similar to the first etching process 804. In various implementations, the operation 708 can be similar to the operation 704 of FIG. 7. For example, an amount of the substrate 304 etched by the etching process 806 may be controlled through a length of time of the etching process 806. As shown in FIG. 10, based on the patterns of the (e.g., laterally shrunken) mask 802, the surface (e.g., back surface side for forming the first silicon lens) may present another donut shape (when viewed from the top), in which the donut shape is presented as a recessed portion with respect to a remaining portion that is overlaid by the mask 802. Specifically, the remaining portion and the recessed portion may form another step, e.g., 807, where the step 805 is disposed below and surrounding the step 807, as indicated in FIG. 10.

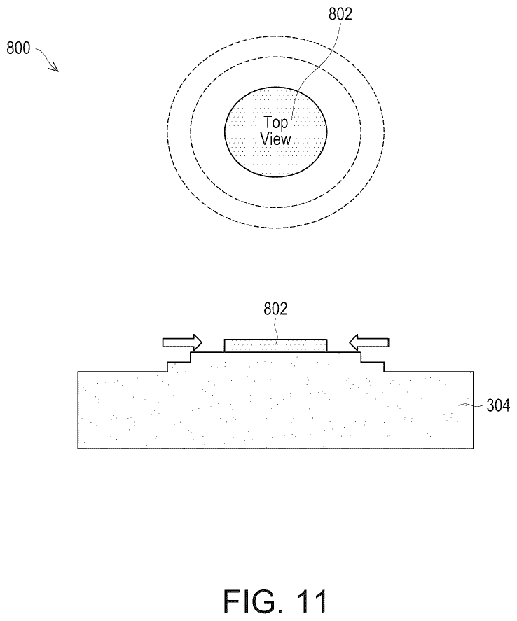

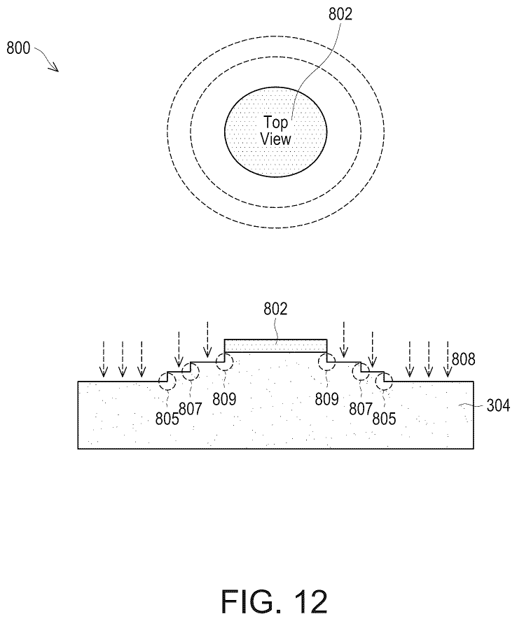

By repeating operations 706 and 708 once, yet another step 809 can be formed on the corresponding surface (e.g., back surface side for the first silicon lens or the front surface side for the second silicon lens) through yet another etching process 808 using a further shrunken mask 802, which is shown in cross-sectional views and top views of FIG. 11 and FIG. 12, respectively. Similarly, the step 809 is formed as being disposed above and surrounded by the preceding step(s), e.g., 807 and 805.

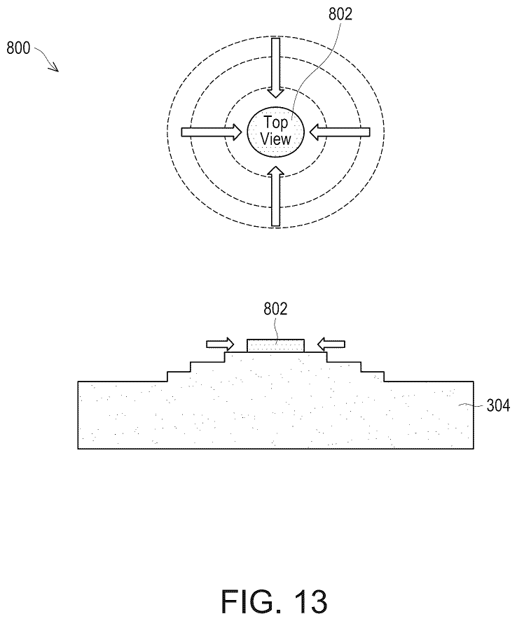

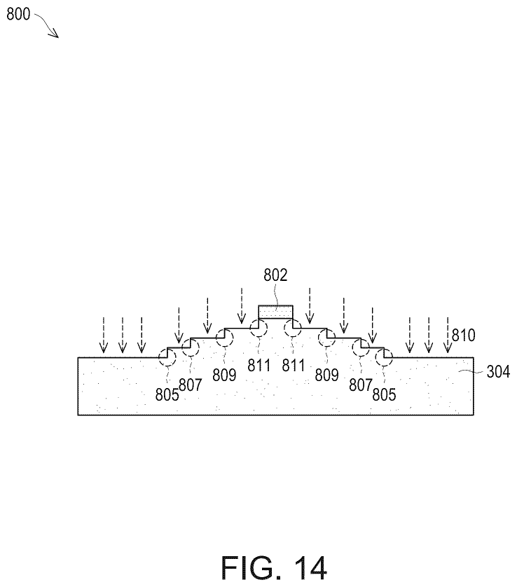

After repeating operations 706 and 708 one or more times, a corresponding number of steps can be found on the corresponding surface of the substrate 304, which can form a staircase profile. For example, another step 811 can be formed on the corresponding surface (e.g., back surface side for the first silicon lens or the front surface side for the second silicon lens) through yet another etching process 810 using a further shrunken mask 802, which is shown in cross-sectional views and top views of FIG. 13 and FIG. 14, respectively. Similarly, the step 811 is formed as being disposed above and surrounded by the preceding step(s), e.g., 809, 807, and 805.

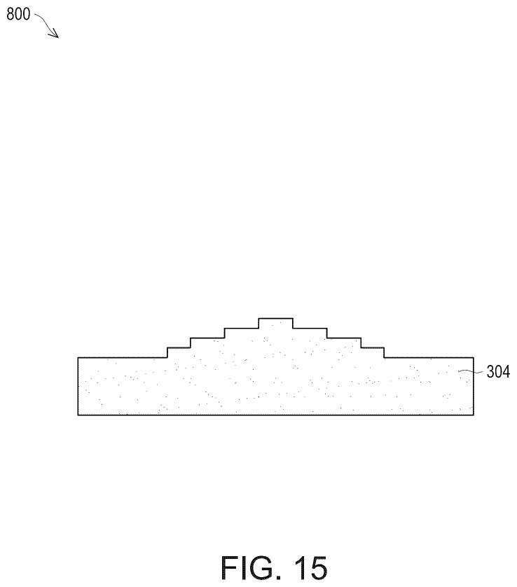

FIG. 15 illustrates a cross-sectional view of the semiconductor package 800 in which the mask 802 is removed, upon a desired staircase profile being formed. In some embodiments, the hard masks can be removed by a phosphoric acid solution at an elevated temperature (e.g., about 170° C.), plasma ashing, wet cleaning, or other suitable techniques to remove the remaining mask 802. In some embodiments, the etching processes performed on the substrate (e.g., 304) can define or determine at least one or both of the thickness (e.g., depth or height) or the diameter of the first and second silicon lenses. For example, relatively more etching processes (e.g., thereby producing more steps) may result in a relatively thicker or wider silicon lens, which may depend on the duration of the individual etching processes or the configuration of the mask 802.

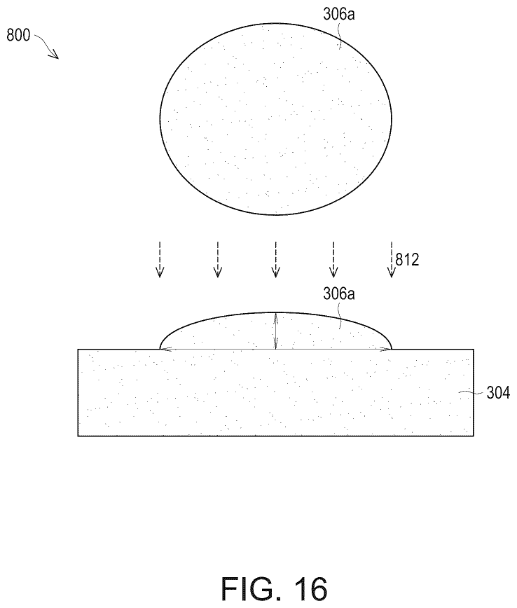

Corresponding to operation 710 of FIG. 7, FIG. 16 is a cross-sectional view and a top view of the semiconductor package 800 in which an etching process 812 is performed to round the steps of the staircase profile, in accordance with various embodiments. The etching process 812 may be a wet etching process. In some embodiments, the etching process 812 can include applying at least one of ammonia solution or nitric acid solution over the corresponding surface to round the staircase profile. For example, the etching process 812 can etch protruding portions of the staircase profile substantially sooner than the steps (e.g., 805, 807, 809, or 811). As such, such protruding portions can be rounded (or smoothen) to form a spherical surface protruding away from the corresponding surface, thereby forming a silicon-based lens (e.g., 306a or 306b) having a plano-convex profile.

Corresponding to operation 604 of FIG. 6, the operations of the method 700 of FIG. 7 can be repeated or iterated to form another silicon lens along the other (opposite) surface side of the silicon substrate. For example, after forming one of the silicon lenses, the silicon substrate (e.g., fixed on a carrier substrate during the fabrication process) can be flipped to expose the other surface side of the silicon substrate. After flipping the silicon substrate, operations of the method 700 can be performed to form the other silicon lens. The first silicon lens (e.g., 306a) may be formed before or after the second silicon lens (e.g., 306b). Although the operations of the method 700, such as corresponding to FIGS. 8-16, may be used to form the first silicon lens (e.g., 306a), in some cases, the operations of the method 700 can be used similarly to form the second silicon lens (e.g., 306b). In such cases, the second silicon lens can be formed on the front side or the second side (e.g., 305A) of the substrate 304 and the first silicon lens can be formed on the back side or the first side (e.g., 305B) of the substrate 304.

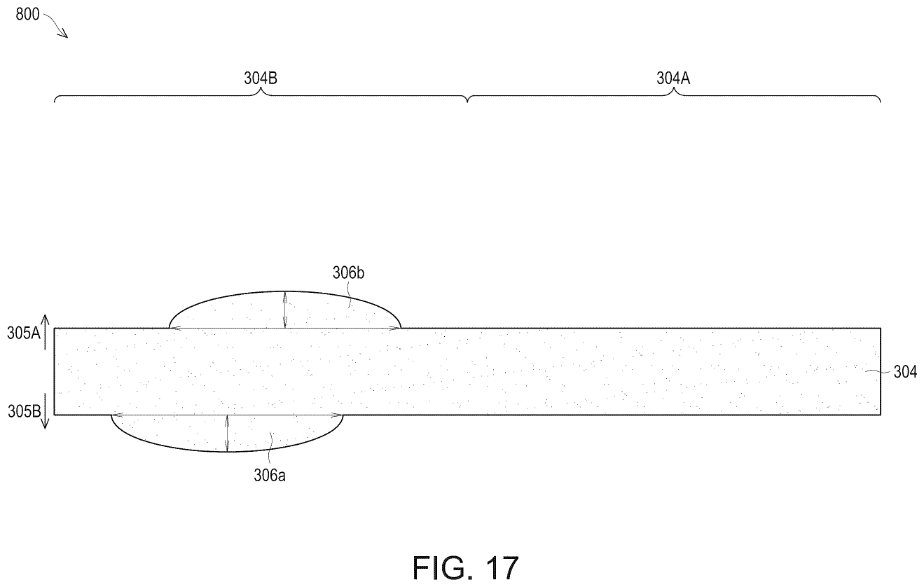

As shown in FIG. 17, and corresponding to the operations 602 and 604 of FIG. 6, the first silicon lens (e.g., 306a) and the second silicon lens (e.g., 306b) can be formed along the corresponding surface on a respective side of the silicon substrate in the first region (e.g., 304B). For example, the silicon-based lens 306a can be formed along the first surface on the first side 305B of the substrate 304. The silicon-based lens 306b can be formed along the second surface on the second side 305A of the substrate 304. The first side 305B is opposite to the second side 305A of the substrate 304. The silicon-based lenses 306 (e.g., 306a and 306b) are formed in the first region 304B. The silicon-based lenses 306 can form a double-sided convex lens, for example.

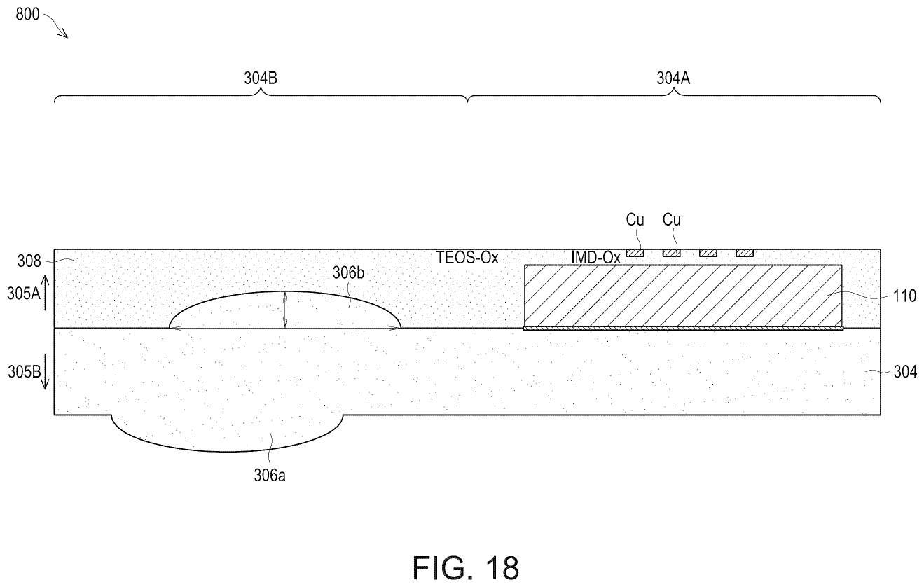

Corresponding to the operation 606, FIG. 18 is a cross-sectional view of the semiconductor package 800 in which an electronic die and a dielectric layer are formed, in accordance with various embodiments. For example, after forming the first silicon lens (e.g., 306a) and the second silicon lens (e.g., 306b), the electronic die can be formed in the second region (e.g., 304A) of the silicon substrate. The second region is laterally next to the first region (e.g., 304B) of the silicon substrate where the first and second silicon lenses are formed. For example, an electronic die (e.g., 110), including a number of electrical device features (e.g., 402) and conductive features (e.g., 406), may be formed over the front side surface (e.g., 305A) of the substrate (e.g., 304). Further, the electronic die 110 may be formed in a second region (e.g., 304A) of the substrate 304 where a silicon-based lenses 306 are not configured to be formed.

After forming the electronic die, the dielectric layer (e.g., 308) can be formed, disposed, or deposited along the front side (e.g., 305A) of the silicon substrate and the surface of the electronic die (e.g., 110). As shown in FIG. 18, for example, the dielectric layer (e.g., 308) can be formed or deposited along the surface (e.g., second surface) of the front side (e.g., second side) of the silicon substrate and the electronic die. The deposited dielectric layer can include a predetermined (e.g., configured) thickness. For example, the dielectric layer can include a thickness of, but is not limited to, greater than 8 μm, with a range of greater than between 0 μm to 50 μm. In some cases, at least one suitable etching technique can be used to remove a portion of or thin down the dielectric layer (e.g., 308).

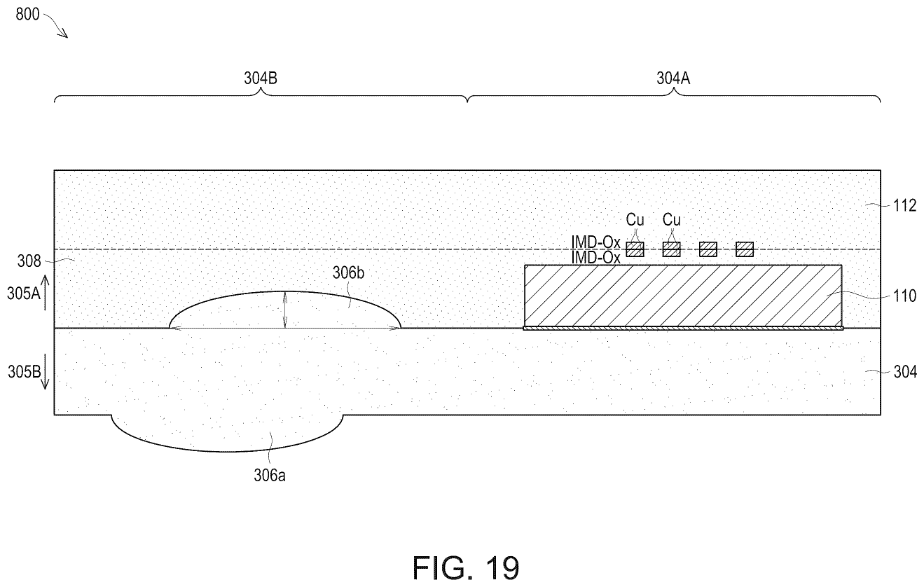

Corresponding to operation 608, FIG. 19 is a cross-sectional view of the semiconductor package 800 in which a photonic die is formed, in accordance with various embodiments. As shown, the photonic die (e.g., 112) is formed over the front side surface (e.g., 305A) of the substrate (e.g., an SOI including the underlying semiconductor material 412, BOX 414, and an overlaying semiconductor material) or along the front side surface of the dielectric layer (e.g., 308). The front side surface of the dielectric layer is opposite from the back side surface of the dielectric layer facing the substrate (e.g., 304). For example, as discussed herein, the photonic die 112 includes a number of optical device features (e.g., 416), a number of waveguides (e.g., 418) with at least a grating coupler (e.g., 420), and a number of conductive features (e.g., 424). The grating coupler (e.g., 420) can be vertically aligned with at least one of the silicon-based lenses (e.g., 306a or 306b), such as described in conjunction with but not limited to at least one of FIGS. 3-4. The conductive features (e.g., 424) can be disposed over the grating coupler (e.g., 420), although not in the optical transmission path.

The photonic die 112 can be attached to the electronic die 110. The two dies can be attached through various bonding techniques such as, for example, hybrid bonding, fusion bonding, direct bonding, dielectric bonding, metal bonding, solder joints (e.g., microbumps), or the like. In some embodiments, the electronic die 110 may be bonded to the photonic die 112, with the conductive features, for example.

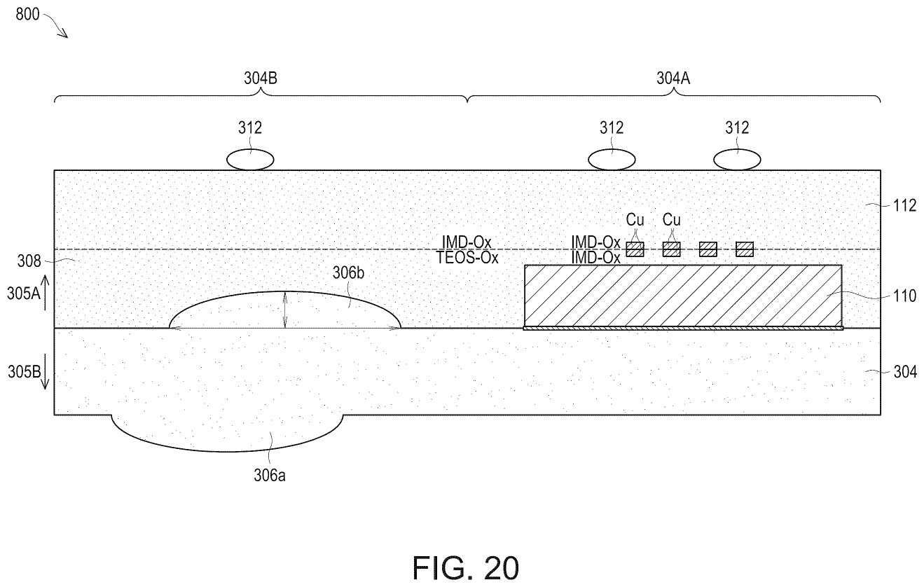

Subsequently, FIG. 20 is a cross-sectional view of the semiconductor package 800 in which one or more conductive connectors (e.g., 312) are formed, in accordance with various embodiments. For example, the conductive connectors 312 may be formed on a front side surface of the substrate (e.g., 304) where the photonic die 112 is formed. As shown, the one or more conductive connectors 312 are formed on a first side of the photonic die 112 (e.g., facing away from the substrate 304) opposite to a second side of the photonic die 112 which faces the substrate 304. In some embodiments, the conductive connectors 312 can be formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 312 may be metal pillars (such as a copper pillar) formed by a sputtering, printing, electro plating, electroless plating, CVD, or the like. The metal pillars may be solder free and have substantially vertical sidewalls.

The conductive connectors 312 can facilitate or provide the connection between the photonic die 112 and the package substrate (e.g., 302). For example, after forming the conductive connectors 312, the semiconductor package 800 can be flipped and attached to the package substrate (e.g., 302), such as shown in conjunction with but not limited to at least one of FIGS. 3-4. By flipping the semiconductor package 800 at this stage, the back side (e.g., 305B) of the silicon substrate can be faced upward, and the front side (e.g., 305A) of the silicon substrate can be faced downward, as shown in FIGS. 3-4, for example. Other structures can be formed, connected, or implemented in connection with the semiconductor package 800, not limited to those described herein.

In one aspect of the present disclosure, a semiconductor device is disclosed. The semiconductor device includes a silicon substrate having a first side and a second side opposite to each other, and further having a first region and a second region. The semiconductor device includes a first silicon lens formed in the first region and along a first surface of the silicon substrate on the first side of the silicon substrate. The semiconductor device includes a second silicon lens formed in the first region and along a second surface of the silicon substrate on the second side of the silicon substrate. The semiconductor device includes a photonic die disposed in the first region and on the second side of the silicon substrate.

In another aspect of the present disclosure, a semiconductor package is disclosed. The semiconductor package includes a substrate disposed over a package substrate. The semiconductor package includes a grating coupler disposed over the substrate. The semiconductor package includes a plurality of first conductive features disposed over the grating coupler. The semiconductor package includes an electronic die disposed over the plurality of first conductive features and including a plurality of second conductive features. The semiconductor package includes a first silicon lens formed along a first surface of a silicon substrate. The semiconductor package includes a second silicon lens formed along a second surface of the silicon substrate, the second surface opposite to the first surface. The electronic die is formed along the second surface of the silicon substrate.

In yet another aspect of the present disclosure, a method for fabricating a semiconductor package is disclosed. The method includes forming a first silicon lens along a first surface on a first side of a silicon substrate and in a first region on the first side. The method includes forming a second silicon lens along a second surface on a second side, opposite side of the silicon substrate and in the first region on the second side. The method includes forming an electronic die on the second side and in a second region laterally next to the first region. The method includes attaching a photonic die to the electronic die on the second side, wherein the photonic die includes a grating coupler vertically aligned with at least one of the first silicon lens or the second silicon lens.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor package, comprising:
forming a silicon substrate comprising a first side and a second side, wherein the first side is exposed;
forming a first silicon lens at the first side of the silicon substrate by at least etching the first side of the silicon substrate;
flipping the silicon substrate to expose the second side; and
forming a second silicon lens at the second side of the silicon substrate by at least etching the second side of the silicon substrate.

2. The method of claim 1, wherein forming each of the first and second silicon lens comprises:
forming a staircase profile from a corresponding surface of the silicon substrate via a plurality of etching steps using a mask; and
rounding the staircase profile to form a corresponding silicon lens.

3. The method of claim 2, wherein forming the staircase profile comprises:
(a) forming the mask over the corresponding surface of the silicon substrate;
(b) etching the silicon substrate using the mask;
(c) laterally shrinking the mask;
(d) etching the silicon substrate using the shrunken mask;
(e) repeating the steps (c) and (d) to form the staircase profile.

4. The method of claim 2, wherein a number of the plurality of etching steps defines at least one of a depth or a diameter of the first and the second lens.

5. The method of claim 1, wherein the silicon substrate comprises a first region and a second region laterally next to the first region.

6. The method of claim 5, further comprising:
forming a dielectric layer on the second side and in the first region of the silicon substrate.

7. The method of claim 6, wherein the dielectric layer includes a thickness of about 0 μm to about 50 μm.

8. The method of claim 5, further comprising:
forming an electronic die on the second side and in the second region of the silicon substrate; and
attaching a photonic die to the electronic die on the second side, wherein the photonic die includes a grating coupler vertically aligned with at least one of the first silicon lens or the second silicon lens.

9. The method of claim 8, wherein the grating coupler includes a thickness of about 100 nm to about 1000 nm.

10. The method of claim 8, wherein the grating coupler is configured to allow a waveguide to receive light through both of the first silicon lens and the second silicon lens.

11. The method of claim 1, wherein the first lens is vertically aligned with the second lens, or wherein the first lens is laterally shifted from the second lens with a distance between about 0 micrometers (μm) and about 100 μm.

12. The method of claim 1, wherein at least one of the first silicon lens or the second silicon lens includes a configuration comprising at least one of:
a thickness of about 1 μm to about 50 μm,
an optical fiber angle of about 5° to about 15°,
a radius of about 100 μm to about 500 μm, or
a diameter of about 10 μm to about 500 μm.

13. The method of claim 12, wherein the configuration of the first silicon lens is same as the second silicon lens, or wherein the configuration of the first silicon lens is different from the second silicon lens.

14. A semiconductor device, comprising:
a silicon substrate having a first side and a second side opposite to each other;
a first silicon lens formed at the first side of the silicon substrate;
a second silicon lens formed at the second side of the silicon substrate; and
a waveguide disposed on the second side of the silicon substrate to receive light via the first silicon lens and the second silicon lens.

15. The semiconductor device of claim 14, wherein the waveguide comprises a grating coupler, wherein the grating coupler is configured to allow the waveguide to receive the light via the first silicon lens and the second silicon lens.

16. The semiconductor device of claim 14, wherein the silicon substrate further comprises a first region and a second region laterally adjacent to the first region, and wherein the first and second silicon lens are disposed in the second region.

17. The semiconductor device of claim 16, further comprising:
a dielectric layer disposed in the first region and on the second side of the silicon substrate;
an electronic die disposed in the second region and on the second side of the silicon substrate; and
a photonic die disposed on the second side of the silicon substrate, wherein the dielectric layer and the electronic die are interposed between the silicon substrate and the photonic die.

18. The semiconductor device of claim 14, wherein wherein at least one of the first silicon lens or the second silicon lens includes comprises at least one of:
a thickness of about 1 μm to about 50 μm,
an optical fiber angle of about 5° to about 15°,
a radius of about 100 μm to about 500 μm, or
a diameter of about 10 μm to about 500 μm.

19. A semiconductor package, comprising:
a substrate disposed over a package substrate;
a first silicon lens formed along a first surface of a silicon substrate;
a second silicon lens formed along a second surface of the silicon substrate, the second surface opposite to the first surface;
a photonic die disposed over the second surface of the silicon substrate;
an electronic die interposed between the photonic die and the silicon substrate; and
a plurality of conductive features extending from at least the photonic die to the electronic die.

20. The semiconductor package of claim 19, further comprising:
a waveguide disposed over the substrate and having a grating coupler to allow the waveguide to receive light via the first silicon lens and the second silicon lens, wherein at least a portion of the plurality of conductive features is disposed over the grating coupler.
